(19) United States
(12) Patent Application Publication
(10) Pub. No.: US 2007/0214890 A1
(43) Pub. Date: Sep. 20, 2007

(54) MEMS resonator using frequency tuning

(76) Inventor: Ranjan Mukherjee, East Lansing, MI (US)

Correspondence Address: HARNESS, DICKEY & PIERCE, P.L.C., P.O. BOX 828, BLOOMFIELD HILLS, MI, 48303, US

(21) Appl. No.: 11/700,240

(22) Filed: Jan. 30, 2007

Related U.S. Application Data
(60) Provisional application No. 60/763,719, filed on Jan. 31, 2006.

(51) Int. Cl. G01P 1/04; G01P 15/097; B81B 3/00

(52) U.S. Cl. 73/514.29; 73/514.36

(57) ABSTRACT

A MEMS sensor having a vibrating cantilevered beam sensing element is provided. The sensor has a drive element which is configured to apply follower forces to a free end of the cantilevered beam. These forces function to change the resonant frequency of the beam.

### CROSS-REFERENCE TO RELATED APPLICATIONS

This application claims the benefit of U.S. Provisional Application 60/763,719, filed Jan. 31, 2006. The disclosure of the above application is incorporated herein by reference.

### FIELD OF THE INVENTION

The present invention relates to MEMS sensors and articularly to a MEMS sensor having a cantilevered beam and more particularly to a cantilevered beam having a force follower mechanism.

### BACKGROUND AND SUMMARY OF THE INVENTION

MEMS oscillators are used in a wide variety of dynamic microscale sensors, such as inertial sensors resonant mode chemical sensors, magnetic resonance force microscopy, accelerometers, and mechanical filters. In all these devices, regulation of the resonant frequency is of paramount importance for maintaining performance. Due to the very nature of MEMS fabrication processes, the resonant frequency of the oscillators cannot be guaranteed at their designed values. Also, changes in temperature and other environmental conditions cause drift in the resonant frequency.

A number of researchers have investigated the use of feedback control in micro- and nano-scale engineering systems. Some of the areas of interest have been inertial sensors, force sensors, Q-control, control of pull-in stability, electrostatic actuators, and mirror position control for optical switches. An important problem that has been largely overlooked is the frequency regulation problem in MEMS oscillators.

Though there has been no work reported on closed-loop control of resonant frequency in MEMS, there are some papers on related topics. Adams et al. proposed adding specially designed tuning electrodes to “tune” both the linear and cubic stiffness of MEMS oscillators in an open-loop fashion. The disclosed system showed an ability to tune the resonators to achieve design goals and compensate for small imperfections due to fabrication. The tuning elements are quite nonlinear and this makes closed-loop control implementation a challenging task. Other related results include resonant frequency tracking in MEMS for fatigue testing, and comprehensive modeling to predict frequency shifts in MEMS oscillators discloses a feedback control scheme was developed to track the natural frequency of MEMS resonators. This is different from the control objective of regulating the resonant frequency at a desired value according to the teaching of the present invention.

One of the fundamental problems in control of structures is spillover which stems from reduced-order models designed for control simplification. Although addressing the problem of spillover, the control algorithm presented herein has the potential to sidestep the spillover problem. For a simple cantilever beam, a control system is presented that will cancel vibrations in the first flexible mode, change stiffness of the system to redistribute energy into new mode shapes, and repeat the procedure until vibrational energy of the beam is completely eliminated. Such an approach requires estimation and control of the first mode of vibration only and will therefore be relatively easy to implement.

The dynamics of a flexible beam are modified under the application of a “follower force.” Control using a follower force has the advantage of a much higher instability limit. This limit is about one order of magnitude higher, than the typical buckling force. Within the stable range, the follower force significantly changes the stiffness of the beam, its natural frequencies, and mode shapes. This provides the scope for control design with less restriction on sensor locations since node locations do not remain fixed but vary with the magnitude of the follower force. The application of a follower force also redistributes energy from one set of modes to another—this can be exploited to design lower order controllers for vibration suppression.

It is an object of the invention to overcome the deficiencies of the prior art. Further, it is an object of the invention to improve control authority in dynamical systems though methodical stiffness variation. In this regard, the methodical variation of stiffness, or selected system parameters, can enrich system dynamics and provide for greater control of its dynamical behavior. It is envisioned that the system is applicable for controlling behavior under both fast and slow parameter excitation with the objective to generalize the approach as well as understand the limits of control authority enhancement.

The present invention overcomes this problem through stiffness variation of the MEMS oscillator in a manner that will regulate the resonant frequency at its desired value. To this end, a cantilever beam MEMS oscillator contains an electrostatic actuator that will apply a tensile force at the tip of the beam. The actuator is designed such that the resonant frequency of the beam can be changed adequately to compensate for drift or manufacturing imperfection. The MEMS oscillator is provided with a feedback control strategy for regulation of the resonant frequency.

Although the invention relates to vibration suppression in the field of structural control, the main objective is to vary the stiffness of the system and exploit the variable structure of the system in controller design. In one embodiment, the system varies stiffness by applying a follower force using a cable-driven mechanism. Another embodiment uses a plurality of charged plates to apply the follower force to the MEMS oscillator.

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

The present invention will become more fully understood from the detailed description and the accompanying drawings, wherein:

FIG. 1 represents a control system block according to the teachings herein;

FIG. 2 represents a cantilever beam;

FIG. 3 represents a plot which is a function of the loads on the beam shown in FIG. 2;

FIGS. 4a and 4b show variations of the resonant frequency as a function of the applied follower force;

FIG. 5 shows a cantilever beam sensor according to the teachings of one embodiment;

FIGS. 6a and 6b represent the teachings of a second cantilever beam sensor;

FIGS. 7a and 7b represent a variation of the beam responses under follower force loadings; and

FIGS. 8a-8d represent an alternate mechanism to apply the follower force to the beam.

### DETAILED DESCRIPTION OF THE PREFERRED EMBODIMENTS

The following description of the preferred embodiments is merely exemplary in nature and is in no way intended to limit the invention, its application, or uses.

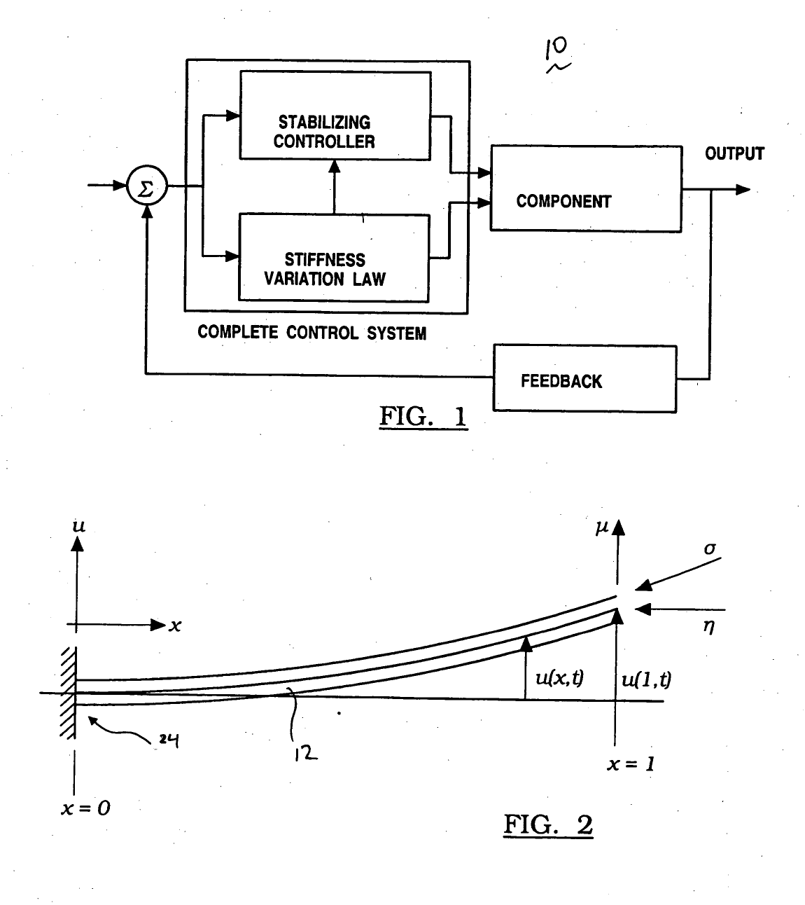

FIG. 1 shows the control system block diagram for dynamical systems that will lend themselves to control authority enhancement through stiffness variation. Although stiffness or parameter variation may not improve control authority in all dynamical systems, it can be used effectively to regulate the resonant frequency in MEMS oscillators, and suppress vibration in flexible beams using a first-mode controller.

The overall control system 10 has a stabilizing controller utilizing a stiffness variation algorithm. The stiffness variation algorithm changes the component stiffness and modifies the control algorithm to account for variation in component parameters. The mechanism for component parameter variation requires additional hardware, but such hardware additions is justified by the benefits of control authority improvement. Similar to the control law, the stiffness variation law is based upon feedback but its time scale of operation may be different from that of the controller. The controller is configured to calculate the resonate frequency of the vibrating member. Additionally, the controller is configured to provide a drive signal to a drive element used to change the stiffness of a vibratory element.

In some systems, stiffness of the component may be changed in a periodic manner to enrich system dynamics. Although such variation in stiffness is discretely turned on and off based on the output of the system, rather than in an open-loop fashion, mathematical tools such as Floquet theory and averaging is useful for analyses. The stable behavior of these systems is ascertained using Lyapunov stability theory.

Other systems may require the stiffness to be varied slowly over a fixed range or discontinuously between several pre-determined levels. In such cases, the main goal is to change the structure of the system, which can then be exploited to simplify control design. When variation in stiffness proceeds slowly but continuously, a singular perturbation method is used to analyze the behavior of the system. Under discontinuous switching, the closed-loop system will behave as a hybrid dynamical system consisting of a family of continuous-time sub-systems and rules governing the switching between them. Most of the work in this area has focused on system stability, and the results indicate that slow switching with sufficient “dwell time” can guarantee stability when the sub-systems are stable. While stability of the sub-systems is preferably regulated by control design, consideration of the loss in performance that may result from a conservative dwell time. If there is excessive loss of performance, the design of switching sequences that will maintain stability must be considered.

FIG. 2 represents a cantilevered beam MEMS sensor and a method for regulating the resonant frequency of cantilever beam MEMS oscillators through variation of the sensor's “effective stiffness”. End loads σ and η offer a systematic means of varying the effective stiffness of beams and hence their natural frequencies and mode shapes. This can be demonstrated by the static force-deflection characteristics of a beam as a function of its end load magnitudes. For a cantilever beam, a tensile end load increases the lateral stiffness, while a compressive end load causes the stiffness to decrease. These changes in effective stiffness are also reflected in the natural frequencies of the beam, which typically increases for a tensile end load and decreases for a compressive load. However, if the end load is a so-called “follower force”, that is, one whose direction remains aligned with the slope at the end of the beam, the effect can be very different from that of an end load that remains parallel to the axis of the undeformed beam. To see this, consider a uniform cantilever beam that has both a follower force F and an axial end load P applied to its free end, and is subjected to a transverse end load Q. A dimensionless version of this is shown in FIG. 2, where terms in the figure are defined below. For small angle analysis, the dimensionless equations of motion and boundary conditions can be written as

$$\frac{{\partial }^{4} u ( χ , t )}{\partial {χ}^{4}} + ( σ + η ) \frac{{\partial }^{2} u ( χ , t )}{\partial {χ}^{2}} + \frac{{\partial }^{2} u ( χ , t )}{\partial {t}^{2}} = 0$$

$$u ( χ , t ) {\vert}_{x = 0} = 0 , \frac{\partial u ( χ , t )}{\partial χ} {\vert}_{χ = 0} = 0 , \frac{{\partial }^{2} u ( χ , t )}{\partial {χ}^{2}} {\vert}_{χ = 1} = 0 , \\ \{ \frac{{\partial }^{3} u ( χ , t )}{\partial {χ}^{3}} {\vert}_{χ = 1} + η \frac{\partial u ( χ , t )}{\partial χ} {\vert}_{χ = 1} + μ \} = 0$$

where u(χ, t) is the transverse deflection of the beam normalized by the beam length L; the beam spatial variable χ is normalized by L and measured such that χ=0 is the fixed end; time has been rescaled by the characteristic frequency \sqrt{EI/ml⁴}, where E,I, and m are the Young's modulus, second moment of cross-sectional area, and mass per unit length of the beam, respectively; and dimensionless load parameters are give by σ=FL²/EI,η=PL²/EI, and μ=QL²/EI. The effective transverse stiffness of the beam can be obtained from the static force-deflection characteristic of the beam. This is obtained by ignoring the inertia term in the equation of motion and solving for the ratio of the transverse end load to the beam tip deflection. The dimensionless result is

$${K}_{eff} \frac{μ}{u ( 1 )} = \frac{λ ( σ + η cos λ )}{sin λ - λ cos λ} , λ {=}^{△} \sqrt{σ + η}$$

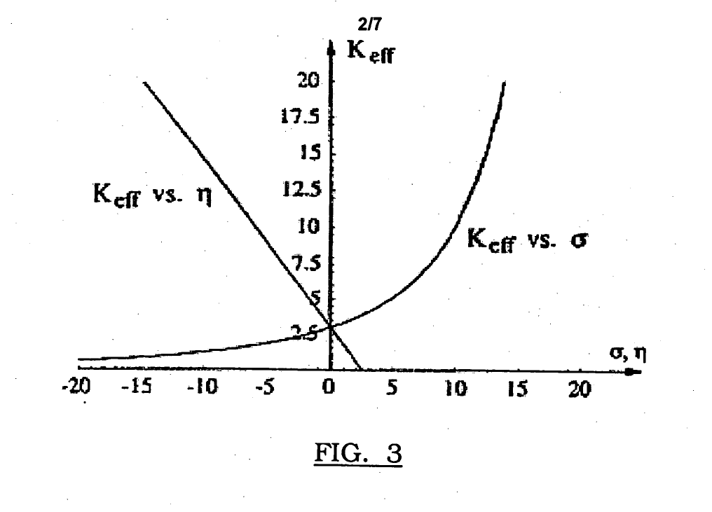

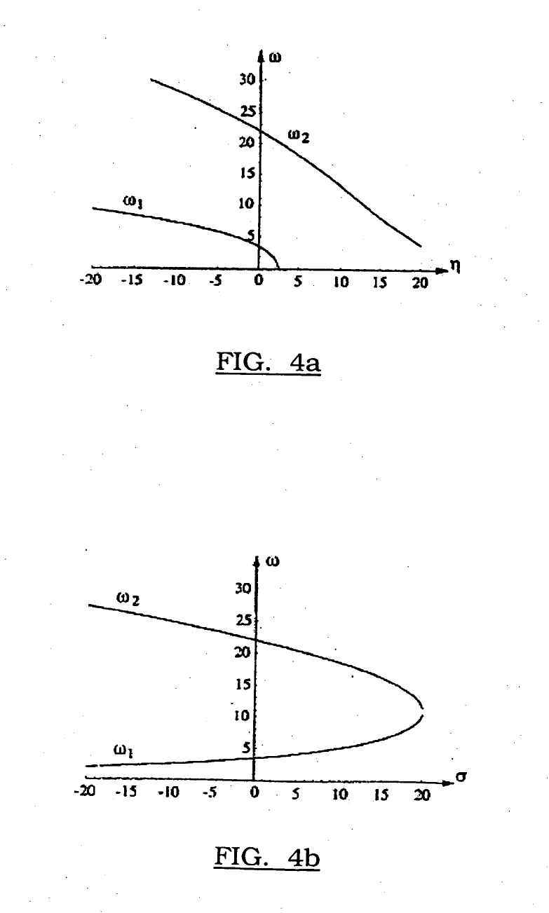

The above result is used to plot K_{eff} as a function of η when σ=0, and as a function of σ when η=0. These plots, shown in FIG. 3, indicate that end load η causes K_{eff} to decrease and buckles the beam when the stiffness goes to zero. The follower force σ, on the contrary, causes K_{eff} to increase. The results make physical sense since it is clear from FIG. 2 that η will aid the transverse load in deflecting the beam while the follower force or will resist it. The static arguments also carry over to the beam's fundamental mode dynamics, which can be obtained from the beam equation above by removing the transverse load, μ=0, and carrying out a standard analysis for the natural frequencies. The results for the first two natural frequencies as a function of end loads are depicted in FIGS. 4(a) and (b). FIG. 4(a) shows the first two frequencies as a function of the axial end load η for zero follower force, i.e. σ=0. This indicates the decreasing nature of the natural frequencies as η increases, and shows the end load at which the beam buckles to be η_{cr}=2.48. FIG. 4(b) shows the same first two natural frequencies as a function of the follower force σ for η=0. Note that as σ increases the first modal frequency increases while the second modal natural frequency decreases. These two frequencies merge, resulting in a flutter instability, at a critical value of the follower force given by σ_{cr}=20.05. Note that one has a significantly larger working range for a compressive follower force as compared to a compressive axial end load.

From the plots in FIGS. 4a and 4b, it can be seen that the slope of stiffness variation is steeper for η (axial force) compared to σ (follower force) about zero nominal values. Since the system relies on electrostatic forces of attraction in MEMS and it is difficult to generate large magnitudes of these forces, the system applies a tensile axial force to increase the resonant frequency of the oscillator. By changing the nature of the end load from a tensile axial force to a tensile follower force, the system decreases the resonant frequency of the oscillator. The procedure for changing the nature of end load from an axial force to a follower force is not trivial but offers to provide a larger range of frequency variation. The range of variation would be considerably smaller if one were to apply a follower force only.

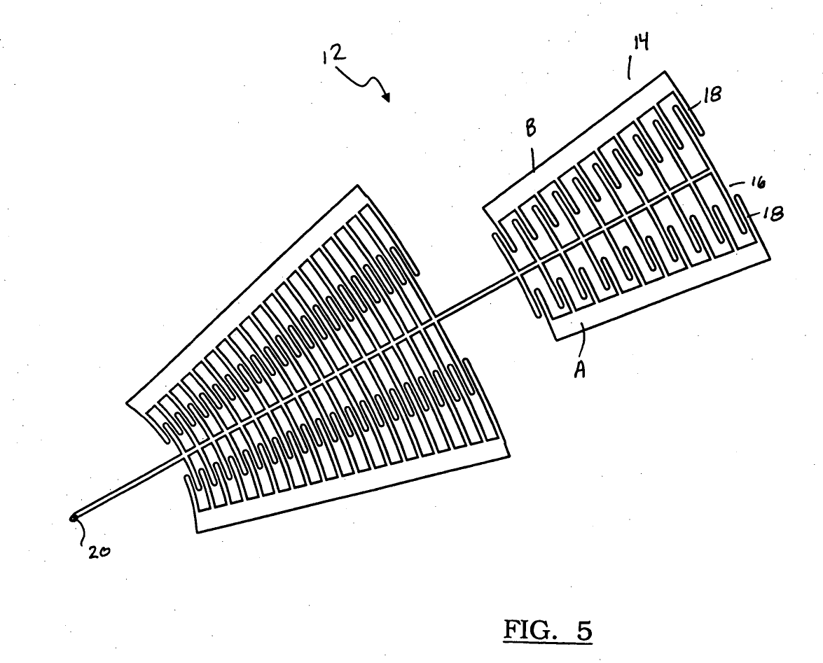

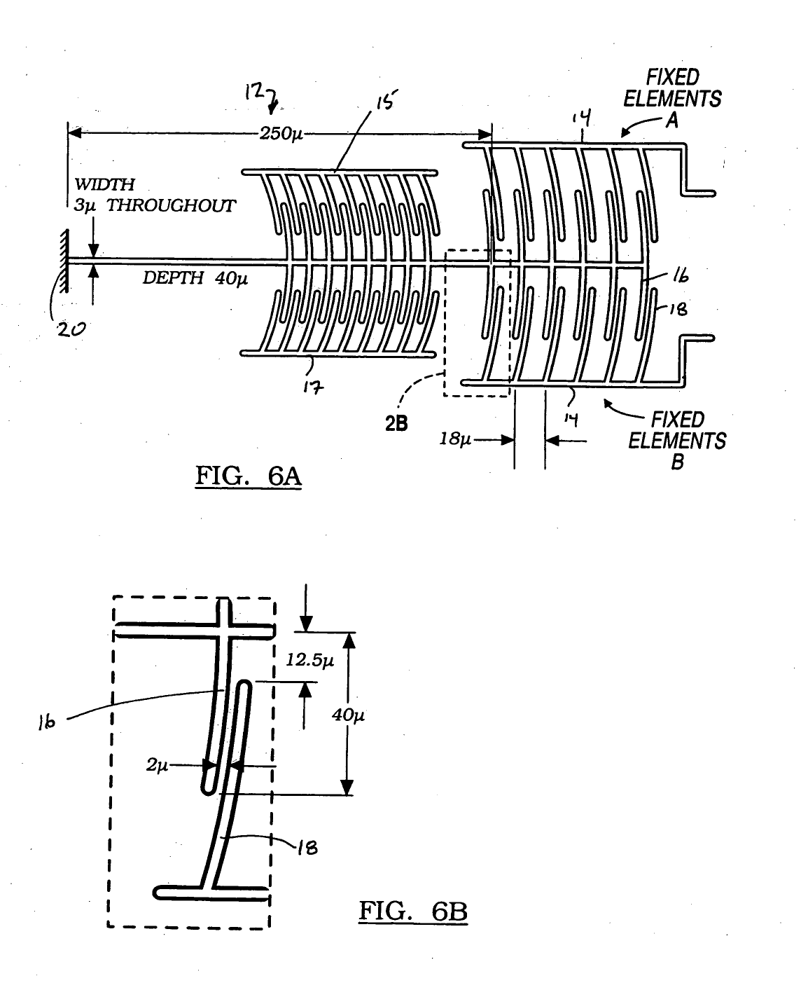

The oscillator 12, shown in FIGS. 5 and 6a, has an actuator 14 at the free end for application of a tensile or compressive end load. The end load is generated by applying a voltage between the structure at the free end and fixed elements, A and B. The oscillator 12 has a plurality of actuator members 16 which interleave with the plates 18 of the fixed actuator elements A and B. If the voltage applied to A and B is the same, the force at the beam tip is a tensile follower force. By sensing the deflection of the beam and applying different voltages between the tip structure and elements A and B, it is possible to generate a tensile force of constant or varying magnitude acting along the axis of the undeformed beam. Of course, this requires proper design to ensure sufficient overlap between the beam tip structure and elements A and B at all times. The comb-like sensor elements on two sides of the beam will serve as the actuator 15 and sensor 16. This sensor 16 functions to measure changes in capacitance to measure displacement of the beam as is known. Optionally, a piezo-electric sensor or strain gauge can be used to measure deformation of the beam.

Differences in polarity of the charges will apply attractor forces on the attractor members 16 and thus apply a tensile force on the oscillator 12. Similarly, when the polarity of the members is the same, the members repel each other placing the oscillator 12 in compression. For small amplitude oscillations, the actuator members 16 and plates 18 can be flat. As seen in FIGS. 6a and 6b, the actuator members 16 and plates 18 can have a radius of curvature which is centered at the anchoring point 20 of the oscillator 12. In this configuration, the forces applied to the oscillator 12 allow for an axial load η of zero and a load σ as applied. The exact number of fingers and the dimensions are variable, but the number of fingers can be based on the following:
a) The first natural frequency of beam is approximately 15.5 KHz. The finite element model used to determine the natural frequency is later used to compute the exact radius of the curved elements to eliminate nonlinear effects.
b) By considering the deflection desired at resonance and assuming a quality factor of 200, the system can compute the static deflection to be generated by the comb actuator. Optionally, this radius can have a center of curvature at the fixation point of the cantilevered beam.
c) Using 50 V between the beam tip structure and the fixed elements A and B, it is possible to apply a tensile follower force equivalent to σ=−0.18. Using the code that generated the plot in FIG. 4(a), it can be shown that this reduces the first natural frequency by 0.6%. By applying different voltages between the fixed elements and the tip structure to generate an axial tensile force equivalent to η=−0.18, it is possible to increase the frequency by 3.3%. A total change of 3.9% (about 600 Hz) in resonant frequency is substantial considering the fact that bandwidth of the resonator is in the range of 75 Hz. However, it is envisioned that 6-8% change should be possible to achieve through careful design.

The comb-like actuator 14 will provide input to the system in the form of sinusoidal excitation, while the sensor will provide the output which is measured by the change in capacitance in the sensor plates as is known. The sensor signal is weak and require appropriate processing.

When external signals at or near the resonant frequency are absent, the oscillator 12 will provide nearly zero output and it will not be possible to estimate the drift in resonant frequency. Furthermore, if the output of the oscillator 12 indicates a drift and the drift is substantially larger than the bandwidth of the system, the output of the system will become negligible as the system attempts to correct the drift. To overcome this observability problem, the system will optically periodically inject a signal at the desired resonant frequency and vary the stiffness of the oscillator to maximize the output amplitude. This will enable the tuning of the resonant frequency to its desired value. A challenging part of implementing this scheme is to apply the right set of voltages to the fixed elements A and B based on the instantaneous deflection of the oscillator such that an axial force or a follower force of desired magnitude can be applied. The system provides the injected signal and end load variation so that the desired tuning can be achieved. This process involves a system being forced near resonance with a time-varying natural frequency, a situation known to be rich in terms of dynamic response.

The use of an end load to modify the modal characteristics of a beam and to exploit these changes in control design is available for other systems. Specifically, one can vary modal frequencies and shapes using an end load, and by switching or smoothly varying between different sets of modal characteristics of a beam. It was noted there that follower forces have much larger operating range than usual axial end loads.

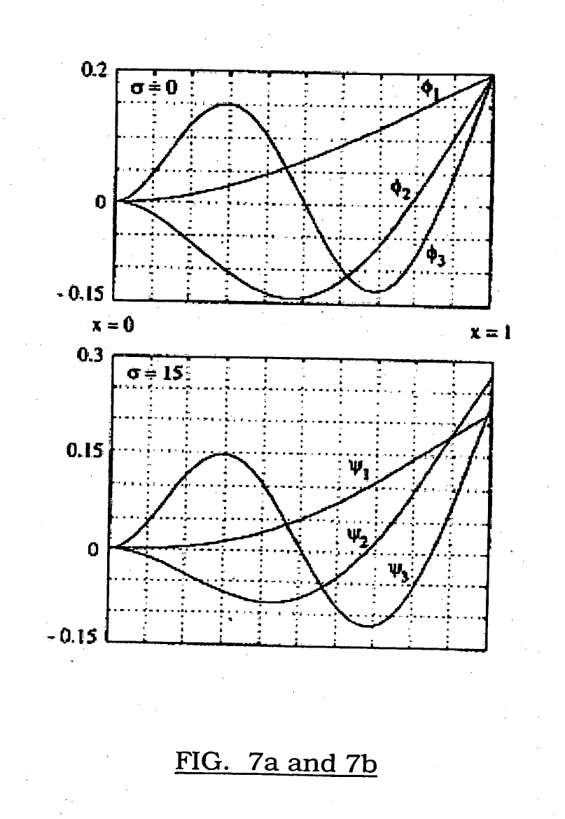

The system focus on the case of a cantilever beam, with a follower force in the present development, since one can achieve significant changes in the first few modes by varying this force. The lower two modes can be altered significantly by varying the follower force between zero and the critical (flutter) value, whereas higher modes are only slightly affected. The first three modes are shown for two different flutter loads in FIGS. 7a and 7b. Note that the first two mode shapes become similar as the flutter load is approached, which is a reflection of the fact that these modes converge towards one another at the flutter load.

The system is considered an idealized static problem wherein the follower force is instantaneously switched between two values, σ₁ and σ₂, and the fundamental modal components are repeatedly removed from the system after each switch. The system will show that such a strategy removes energy from the beam, including higher modes, in a systematic manner, and requires only that one be able to control the fundamental mode corresponding to each of the two values of σ. For the calculations the attendant normalized mode shapes for σ₁, and σ₂ as Φⱼ(χ) and φⱼ(χ), respectively. If one starts with a beam deflection u₀(χ) and an end load σ₁, when one can write u₀(χ)=Σⱼ₌₁^{N}δⱼΦⱼ (χ) where N denotes the modal truncation level and the δⱼ s are the modal amplitude components. Assuming that one can remove the first mode, the resulting shape is given by
u₁(χ)=u₀(χ)−δ₁Φ₁(χ)=Σⱼ₌₂^{N}δⱼΦⱼ(χ)

At this point the end load is switched to σ₂ and the shape is now conveniently expressed as u₁(χ)=Σⱼ₌₁^{N}βⱼφⱼ(χ). It is assumed that the first mode is again removed while σ=σ₂, resulting in the shape U₂(χ)=Σⱼ₌₂^{N}βⱼφⱼ(χ). The end load is then switched back to σ₁ where the shape can then be expressed by
u₂(χ)=Σⱼ₌₁^{N}γⱼΦⱼ(χ)

This completes one cycle of the process, and one is interested in how the new modal coefficients, the γⱼ's are related to the originals, the δⱼ's. This is conveniently described by a linear mapping γ=Mδ, where γ and δ are the vectors of modal coefficients. This mapping can be developed by a sequence of calculations that use modal projections for each level of the follower force and removing the first mode at each stage. The calculations must account for the fact that the basic operator of the system with end loads, L_{σ}, defined as L_{σ}(u)=(∂⁴/∂χ⁴)+σ(∂²u/∂χ²) is not self-adjoint with follower force boundary conditions. This necessitates using the adjoint of the operator for the modal projections at each step of the process. The adjoint operator is denoted as L_{σ}* and its eigenfunctions are given by Φᵢ * and φⱼ * for follower loads σ₁ and σ₂, respectively. Carrying out the mathematical steps it is found that the mapping between modal coefficients is linear and can be expressed as

$${γ}_{n} = {\sum }_{j = 2}^{N} {\sum }_{k = 2}^{N} {Λ}_{nj} {Γ}_{jk} {δ}_{k} , n = 1 , 2 , … , N , {Λ}_{nj} {=}^{△} 〈 {ϕ}_{n}^{*} , {φ}_{j} 〉 , {Γ}_{jk} {=}^{△} 〈 {φ}_{j}^{*} , {ϕ}_{k} 〉$$

where (f,g) is the inner product of functions f and g defined by f₀¹fgdχ. The convergence of this process depends on the N×N linear operator M, which can be constructed as follows: The first column contains all zeros since the first modal coefficient was zeroed out. The remaining columns are filled in by the coefficients from ΛₙⱼΓⱼₖ, n=1,2, . . . , N,k=2,3, . . . , N. If all eigenvalues of M lie inside the unit circle, the process will converge, implying that all modes under consideration die out under repeated cycling and removal of the first relevant mode. The rate of convergence (or divergence) is dictated by these eigenvalues. Note that, if successful, this decay of all included modes is accomplished by controlling only one mode in each domain.

An example of using the cantilever beam with σ₁=0,σ₂=15 using N=4 modes derived to demonstrate the methodology. In this case the matrix for the map is developed using the results derived above and it is found that all of the eigenvalues have modulus much less than unity. Note that M will always have one zero eigenvalue since the first modal coefficient is zeroed out. Hence, for this low-dimensional version of the static process, energy is very quickly removed from all modes under consideration.

Several issues must be considered if one is to implement such a scheme in a structural control setting. The system can be generalized to include that the modal coefficients are time-dependent, and therefore the effectiveness of this control is linked to the strategy used for switching the follower force. Optionally, the system can be configured to continually vary it, but on a slow time scale compared to the beam dynamics. In this case, the tools of composite control, singular perturbation, and invariant manifolds may be of use in developing suitable control methods. In addition, variations of the end load will generally do work on the system and therefore affect its overall energy level. It is expected that this work is small, due to the stiff nature of the beam in the axial direction. In order to account for this, a more complete model for the beam must be used, one that includes axial degrees of freedom. Also, the issue of modal convergence looms large, due to spillover and convergence issues. Optionally, one might use a combination of axial end load and follower load to provide countering effects that offer a larger range of end loads and more variability in mode shapes.

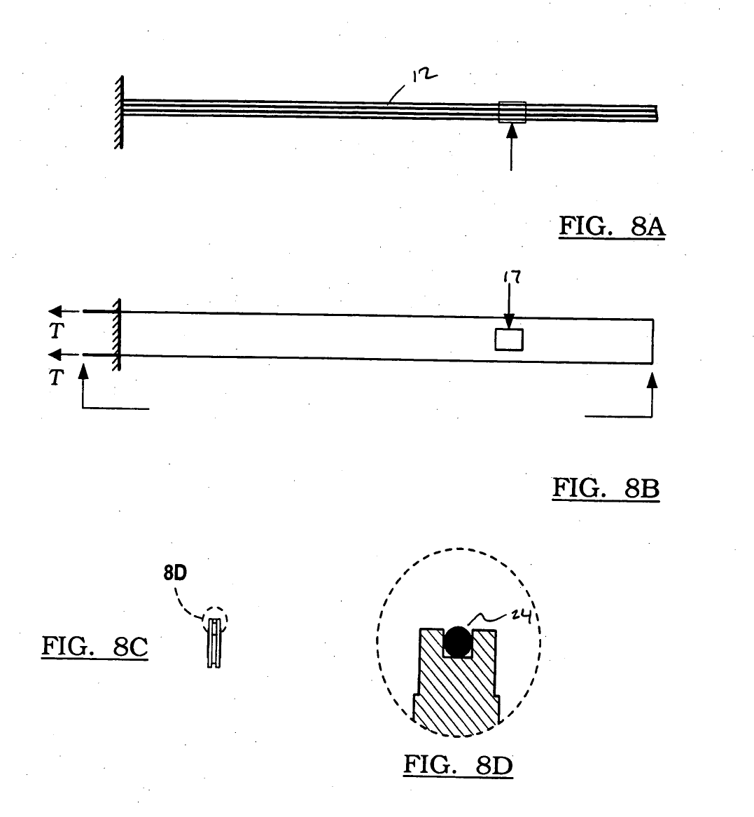

FIGS. 8a-8d represent a system according to the teachings of an alternate embodiment. Shown is a cantilevered beam defining a fiber accepting slot 24. Disposed within the slots is a fiber configured to apply compression forces to the beam. By varying the tension on the fibers, the compressive forces can be applied. These forces can be of the σ or η type.

To apply a compressive follower force, very thin slots are machined in the top and bottom faces of the cantilever beam along its length, as shown in FIGS. 8a-8d. A Kevlar cable is placed in the slot and wrapped around the front face. They are positioned such that a tension in cable generates a follower force. The tension mechanism, not shown in the figure, is designed to regulate the cable tension and effectively vary beam stiffness. A pair of piezo-electric actuators and sensors placed on opposite sides of the beam is used to cancel the first mode of vibration. The actuator and sensor may be collocated but their optimal location is determined through analysis.

The description is merely exemplary in nature and, thus, variations that do not depart from the gist of the invention are intended to be within the scope of the disclosure. For example, the control system presented is applicable for stiffness variation in diverse problems that include disturbance rejection in magnetic bearings, resonant frequency control of MEMS oscillators, and vibration suppression in flexible structures. The time scale for stiffness variation will depend on the system under consideration and limitations of experimental hardware. Such variations are not to be regarded as a departure from the spirit and scope of the invention.

What is claimed is:

1. A sensor comprising:
a sensing element having a vibrating member with a first stiffness; and
a drive element coupled to the vibrating member, said drive element configured to apply force to the vibrating member to change the stiffness of the vibrating member from the first stiffness to a second stiffness.

2. The sensor according to claim 1 wherein the vibrating member has a first resonant frequency at the first stiffness and a second resonant frequency at the second stiffness.

3. The sensor according to claim 1 wherein the vibrating member is a cantilevered beam.

4. The sensor according to claim 1 wherein the drive element applies a follower force to the vibrating member.

5. The sensor according to claim 1 wherein the drive element comprises a plurality of charged plates disposed on the vibrating member.

6. The sensor according to claim 1 wherein the vibrating member comprises a sensing comb.

7. The sensor according to claim 1 wherein the drive element is configured to apply one of a σ force, a η force, or combination thereof to the vibrating member.

8. The sensor according to claim 1 wherein the drive element is a cable.

9. A sensor comprising:
a cantilevered beam sensing member having a fixed end and a free end; and
a drive element configured to apply force to said free end to change the stiffness of the sensing member.

10. The sensor according to claim 9 wherein the drive element is configured to apply one of a σ force, a η force, or combinations thereof to the vibrating member.

11. The sensor according to claim 9 wherein the drive element is configured to apply one of a plurality of load vectors to said free end.

12. The sensor according to claim 9 further comprising a controller configured to produce a signal to drive the drive element to change the stiffness of the beam.

13. The sensor according to claim 12 wherein the controller is configured to provide a signal to the drive element to change the resonant frequency of the beam.

14. The sensor according to claim 9 wherein the drive element is configured to apply a compressive force to the beam.

15. The sensor according to claim 9 wherein the drive element is configured to apply a tensile load to the beam.

16. The sensor according to claim 9 wherein the drive element comprises a plurality of charged plates.

17. The sensor according to claim 16 wherein the charged plates are curved.

18. The sensor according to claim 17 wherein the center of curvature of the curved plates is located about the fixed end of the beam.

19. A method of controlling a vibrating beam sensor comprising:
measuring a first resonant frequency of the beam sensor; and
applying a force to the beam sensor to change a beam resonant frequency from said first resonant frequency to a second resonant frequency.

20. The method according to claim 19 wherein applying a force is applying a force to a first end of the beam.

21. The method according to claim 19 wherein applying a force is applying a follower force.

22. The method according to claim 19 wherein applying a force is applying one of a σ force, a η force, or combinations thereof to the vibrating member.

23. The method according to claim 19 wherein sensing a resonant frequency is sensing deflection of the beam.

24. The method according to claim 23 wherein sensing the deflection of the beam is measuring one of a change in capacitance from a capacitive sensor, a change in resistance from a strain gauge, or a change in charge from a piezo electric sensor.

25. A sensor comprising:
a sensing element having a vibrating cantilevered beam with a first stiffness;
a drive element coupled to the vibrating member, said drive element configured to apply force to the vibrating member to change the stiffness of the vibrating member from the first stiffness to a second stiffness; and
wherein the vibrating member has a first resonant frequency at the first stiffness and a second resonant frequency at the second stiffness.

26. The sensor according to claim 25 wherein the drive element applies a follower force to the vibrating member.

27. The sensor according to claim 26 wherein the drive element comprises a plurality of charged plates disposed on the vibrating member.

28. The sensor according to claim 27 wherein the vibrating member comprises a sensing comb configured to sense the movement of the cantilevered beam.

29. The sensor according to claim 28 comprising a controller configured to calculate the first resonant frequency and the second resonant frequency.

30. The sensor according to claim 29 wherein the controller is further configured to provide a drive signal to the drive element.
